(19) United States
(12) Patent Application Publication
(10) Pub. No.: US 2025/0287665 A1
(43) Pub. Date: Sep. 11, 2025

(54) OXIDE TRANSISTOR AND METHOD FOR MANUFACTURING SAME

(71) Applicant: JUSUNG ENGINEERING CO., LTD., Gwangju-si, Gyeonggi-do (KR)

(72) Inventors: Il Houng PARK, Gwangju-si, Gyeonggi-do (KR); Won Ju OH, Gwangju-si, Gyeonggi-do (KR); Seung Hyun CHO, Gwangju-si, Gyeonggi-do (KR); Chul Joo HWANG

(21) Appl. No.: 18/860,622

(22) PCT Filed: May 15, 2023
(86) PCT No.: PCT/KR2023/006523

§ 371 Date: Oct. 25, 2024

(30) Foreign Application Priority Data
May 24, 2022 (KR) 10-2022-0063330
Jun. 28, 2022 (KR) 10-2022-0078829
Jul. 8, 2022 (KR) 10-2022-0084539

(51) Int. Cl. H10D 62/80; H01L 21/02; H10D 30/00; H10D 30/01

(52) U.S. Cl. CPC H10D 62/875; H01L 21/02565; H01L 21/0262; H10D 30/0191; H10D 30/027; H10D 30/504

(57) ABSTRACT

The present inventive concept provides a method of manufacturing an oxide transistor, the method comprising: a step of forming a first channel layer by supplying a gas containing indium (In) and zinc (Zn) and supplying a gas containing oxygen; a step of forming a spacer on the first channel layer by supplying a gas containing gallium (Ga) and supplying a gas containing oxygen; and a step of forming a second channel layer on the spacer by supplying a gas containing indium (In) and zinc (Zn) and supplying a gas containing oxygen, and an oxide transistor made by the method.

### TECHNICAL FIELDS

The present inventive concept relates to an oxide transistor and a method of manufacturing the same, and more particularly, to an active layer of an oxide transistor.

### BACKGROUND ART

The transistor includes a gate electrode, an active layer, a source electrode, and a drain electrode. In this case, a silicon semiconductor material or an oxide semiconductor material may be used as a material of the active layer. A transistor using an oxide semiconductor material as a material of the active layer is generally referred to as an oxide transistor.

Conventional oxide transistors use a single layer of metal oxide such as IZO as the active layer, and in this case, there is a limit to improving the mobility of charges and it is not easy to implement the desired threshold voltage range.

### DISCLOSURE

### Technical Problem

The present inventive concept is devised to solve the above-described problem, and it is an object of the present inventive concept to provide an oxide transistor capable of improving the mobility of charges and easily implementing a desired threshold voltage range, and a method of manufacturing the same.

### Technical Solution

In order to achieve the above object, according to an embodiment of the present inventive concept, a method of manufacturing an oxide transistor comprises a step of forming a first channel layer by supplying a gas containing indium (In) and zinc (Zn) and supplying a gas containing oxygen; a step of forming a spacer on the first channel layer by supplying a gas containing gallium (Ga) and supplying a gas containing oxygen; and a step of forming a second channel layer on the spacer by supplying a gas containing indium (In) and zinc (Zn) and supplying a gas containing oxygen.

According to another embodiment of the present inventive concept, an oxide transistor comprises a first channel layer including indium-zinc oxide (InZnO); a second channel layer including indium-zinc oxide (InZnO) on the first channel layer; and a spacer including gallium oxide (GaO) between the first channel layer and the second channel layer.

According to another embodiment of the present inventive concept, a method of manufacturing an oxide transistor comprises a step of forming a first channel layer by sequentially supplying a gas containing indium (In) precursor and oxygen, and a gas containing zinc (Zn) precursor and oxygen; a step of forming a spacer on the first channel layer by supplying a gas containing gallium (Ga) precursor and oxygen; and a step of forming a second channel layer on the spacer by sequentially supplying a gas containing indium (In) precursor and oxygen, and a gas containing zinc (Zn) precursor and oxygen.

### ADVANTAGEOUS EFFECT

According to the present inventive concept as described above, there are the following effects.

According to one embodiment of the present inventive concept, since the active layer includes a first channel layer, a second channel layer, and a spacer disposed between the first channel layer and the second channel layer, a band gap of the active layer is controlled to improve mobility of charges.

According to one embodiment of the present inventive concept, by appropriately selecting the material of the spacer, the mobility of charges is adjusted, thereby facilitating the adjustment of the threshold voltage Vth of the transistor.

According to another embodiment of the present inventive concept, since the active layer has a structure in which a spacer is formed between the first channel layer and the second channel layer with different charge mobility, even if the thickness of the active layer increases, a stable oxide transistor may be obtained without increasing the output voltage OV.

### Description of Drawings

FIG. 1 illustrates a schematic cross-sectional view of an oxide transistor according to an embodiment of the present inventive concept.

FIGS. 2A to 2F illustrate schematic cross-sectional views of a manufacturing process of an oxide transistor according to an embodiment of the present inventive concept.

### MODE FOR THE INVENTIVE CONCEPT

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present specification are used, another part may be added unless “only” is used. The terms of a singular form may include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other, or may be carried out together in co-dependent relationship.

Hereinafter, embodiments of the present disclosure will be described in detail with reference to the accompanying drawings. In adding reference numerals to elements of each of the drawings, although the same elements are illustrated in other drawings, like reference numerals may refer to like elements.

Hereinafter, a preferable embodiment of the present inventive concept will be described in detail with reference to the accompanying drawings.

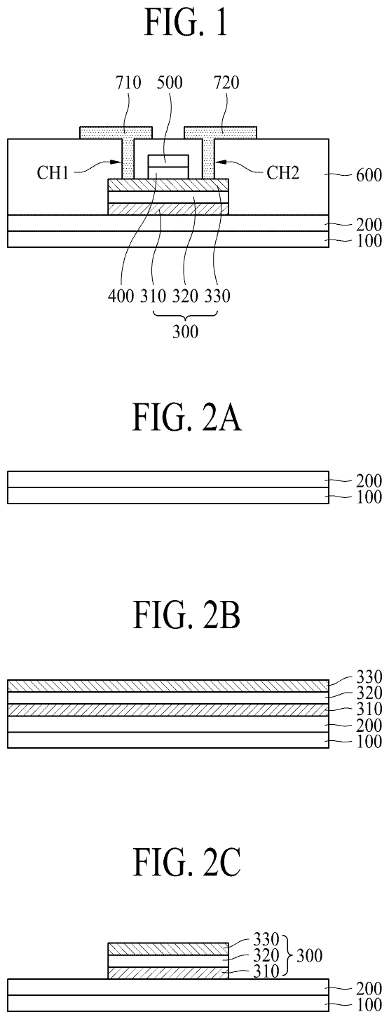

FIG. 1 illustrates a schematic cross-sectional view of an oxide transistor according to an embodiment of the present inventive concept.

As shown in FIG. 1, oxide transistor according to an embodiment of this inventive concept includes a substrate 100, a barrier layer 200, an active layer 300, a gate insulating layer 400, a gate electrode 500, an interlayer insulating layer 600, a source electrode 710, and a drain electrode 720.

The substrate 100 may be made of various materials known in the art, such as glass, plastic, or a semiconductor substrate.

The barrier layer 200 may be formed between the substrate 100 and the active layer 300 to prevent the material contained in the substrate 100 from diffusing to the active layer 300 during the deposition process of the active layer 300. In addition, the barrier layer 200 may play a role in preventing external moisture or oxygen from penetrating the active layer 300 through the substrate 100.

The barrier layer 200 may include silicon oxide, but is not limited thereto.

The active layer 300 is patterned on the barrier layer 200.

The active layer 300 includes a first channel layer 310, a spacer 320, and a second channel layer 330. The first channel layer 310 is formed on the barrier layer 200, the spacer 320 is formed on the first channel layer 310, in particular, between the first channel layer 310 and the second channel layer 330, and the second channel layer 330 is formed on the spacer 320. The first channel layer 310, the spacer 320, and the second channel layer 330 may be formed in-situ in one chamber.

The first channel layer 310, the spacer 320, and the second channel layer 330 may be patterned in the same structure. That is, one end of the first channel layer 310, spacer 320, and second channel layer 330 may match each other, and the other end of the first channel layer 310, spacer 320, and second channel layer 330 may match each other.

The first channel layer 310 may include indium-zinc oxide (InZnO). The thickness of the first channel layer 310 may be in the range of 50 to 100 Å.

The spacer 320 may include gallium oxide (GaO). The spacer 320 may further include indium (In), and thus may include indium-gallium oxide (InGaO). Alternatively, the spacer 320 may further include zinc (Zn), and thus may include gallium-zinc oxide (GaZnO). In addition, the spacer 320 may further include indium (In) and zinc (Zn), and may include indium-gallium-zinc oxide (InGaZnO). The spacer 320 may further include a dopant.

The spacer 320 may function as a buffer layer between the first channel layer 310 and the second channel layer 330 to properly distribute charges to the first channel layer 310 or the second channel layer 330.

In the case of the oxide transistor according to this inventive concept, since the active layer 300 includes the spacer 320, the band gap of the active layer 300 is adjusted to improve the mobility of charges. In the conventional case, it is difficult to obtain an oxide transistor having a charge mobility of 50 (cm²/V·s), but the oxide transistor according to the present inventive concept may have a charge mobility of 50 (cm²/V·s) or more. In addition, by properly selecting the material of the spacer 320, the mobility of the charge is adjusted, making it easier to adjust the threshold voltage (Vth) of the transistor.

A thickness of the spacer 320 may be thinner than each of a thickness of the first channel layer 310 and a thickness of the second channel layer 330, respectively. Specifically, the thickness of the spacer 320 may be in the range of 10 Å to 50 Å. If the thickness of the spacer 320 exceeds 50 Å, the charge mobility of the active layer 300 may decrease, and if the thickness of the spacer 320 is less than 10 Å, the buffer function between the first channel layer 310 and the second channel layer 330 may decrease.

The charge mobility of the spacer 320 is lower than each of the charge mobility of the first channel layer 310 and the charge mobility of the second channel layer 330.

The second channel layer 330 may include indium-zinc oxide (InZnO). The thickness of the second channel layer 330 may be in the range of 50 Å to 100 Å.

The content of indium in the first channel layer 310 may be higher than the content of indium in the second channel layer 330, and thus the charge mobility of the first channel layer 310 may be greater than that of the second channel layer 330.

In some cases, the content of indium in the second channel layer 330 may be higher than the content of indium in the first channel layer 310, and thus the charge mobility of the second channel layer 330 may be greater than that of the first channel layer 310.

According to this inventive concept, since the active layer 300 has a structure in which the spacer 320 is formed between the first channel layer 310 and the second channel layer 330 having different charge mobility, it is possible to obtain a stable oxide transistor without increasing the output voltage OV even though the thickness of the active layer 300 increases.

The gate insulating layer 400 is formed on the active layer 300. In particular, the gate insulating layer 400 is between the active layer 300 and the gate electrode 500. The gate insulating layer 400 may be made of an inorganic insulating material such as silicon oxide or silicon nitride, but is not limited thereto.

The gate electrode 500 is patterned on the gate insulating layer 400. The gate electrode 500 and the gate insulating layer 400 are patterned so that a part of the upper surface of the active layer 300 may be exposed.

The interlayer insulating layer 600 is formed on the gate electrode 500 to cover the active layer 300 and the gate electrode 500. The interlayer insulating layer 600 is equipped with a first contact hole CH1 and a second contact hole CH2, and a part of the active layer 300 is exposed by the first contact hole CH1 and the second contact hole CH2.

The source electrode 710 and the drain electrode 720 are formed on the interlayer insulating layer 600. The source electrode 710 is in contact with one side of the active layer 300, more specifically, the upper surface of one side of the second channel layer 330 through the first contact hole CH1. The drain electrode 720 is in contact with the other side of the active layer 300, more specifically the upper surface of the other side of the second channel layer 330 through the second contact hole CH2.

The above describes an oxide transistor with a so-called top gate structure in which the gate electrode 500 is located above the active layer 300, and this inventive concept includes an oxide transistor with a so-called bottom gate structure in which the gate electrode 500 is located below the active layer 300.

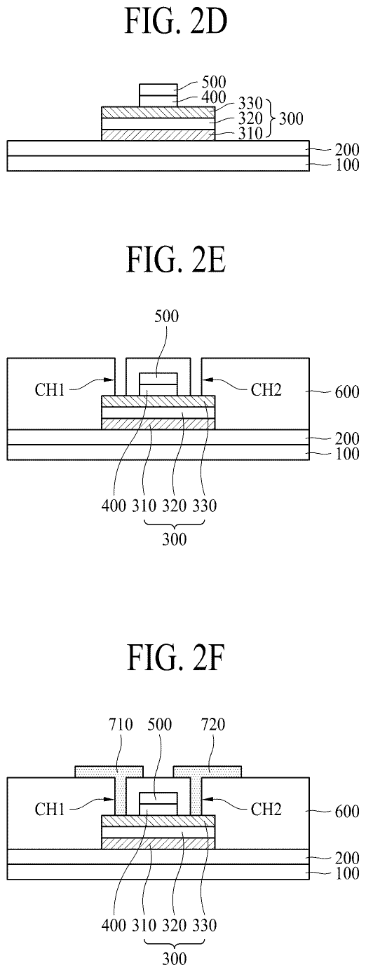

FIGS. 2A to 2F illustrate schematic cross-sectional views of a manufacturing process of an oxide transistor according to an embodiment of the present inventive concept, which relates to a manufacturing process of an oxide transistor according to FIG. 1 described above.

First, as shown in FIG. 2A, a barrier layer 200 is formed on a substrate 100.

Next, as shown in FIG. 2B, a first channel layer 310, a spacer 320, and a second channel layer 330 are formed on the barrier layer 200.

The first channel layer 310 is formed on the barrier layer 200, the spacer 320 is formed on the first channel layer 310, and the second channel layer 330 is formed on the spacer 320.

The first channel layer 310, the spacer 320, and the second channel layer 330 may be formed in-situ in one deposition chamber.

The first channel layer 310 may include indium-zinc oxide (InZnO) formed by supplying a gas containing indium (In) and zinc (Zn) into a chamber and supplying a gas containing oxygen into the chamber. A purge process of supplying a purge gas is performed between a process of supplying one gas and a process of supplying another gas, which is applied to the formation of the first channel layer 310, spacer 320, and second channel layer 330.

The first channel layer 310 may be formed by sequentially supplying a gas containing indium (In) precursor and oxygen, and a gas containing zinc (Zn) precursor and oxygen, and there is no particular order in supplying these gases.

The process of forming the first channel layer 310 may be performed by an ALD process of repeatedly supplying the gas containing indium (In) precursor and oxygen to form an InO layer and supplying the gas containing zinc (Zn) precursor and oxygen to form an ZnO layer. At this time, the process of forming the InO layer and the ZnO layer may be repeatedly performed so that the thickness of the first channel layer 310 is in the range of 50 Å to 100 Å.

The spacer 320 may include gallium oxide (GaO) formed by supplying a gas containing gallium (Ga) into the chamber and supplying a gas containing oxygen into the chamber.

The spacer 320 may be formed by supplying a gas containing a gallium (Ga) precursor and oxygen.

The process of forming the spacer 320 may be performed by an ALD process of repeatedly supplying a gas containing the gallium (Ga) precursor and oxygen to form a GaO layer. In this case, the process of forming the GaO layer may be repeatedly performed such that the thickness of the spacer 320 is in the range of 10 Å to 50 Å.

The spacer 320 may include indium-gallium oxide (InGaO) formed by supplying a gas containing gallium (Ga) into the chamber, supplying a gas containing indium (In) into the chamber, and supplying a gas containing oxygen into the chamber.

The spacer 320 may be formed by sequentially supplying a gas containing a gallium (Ga) precursor and oxygen, and a gas containing an indium precursor and oxygen, and there is no particular order in supplying these gases.

The process of forming the spacer 320 may be performed by an ALD process of repeatedly supplying the gas containing a gallium (Ga) precursor and oxygen to form a GaO layer and supplying the gas containing indium (In) precursor and oxygen to form an InO layer. At this time, the process of forming the GaO layer and the InO layer may be repeatedly performed so that the thickness of the spacer 320 is in the range of 10 Å to 50 Å.

The spacer 320 may include indium-gallium oxide (InGaO) formed by supplying a gas containing gallium (Ga) into the chamber, supplying a gas containing indium (In) into the chamber, and supplying a gas containing oxygen into the chamber.

The spacer 320 may be formed by sequentially supplying a gas containing a gallium (Ga) precursor and oxygen, and a gas containing indium precursor and oxygen, and there is no particular order in supplying these gases. The process of forming the spacer 320 may be performed by an ALD process of repeatedly supplying the gas containing a gallium (Ga) precursor and oxygen to form a GaO layer and supplying the gas containing indium (In) precursor and oxygen to form an InO layer. At this time, the process of forming the GaO layer and the InO layer may be repeatedly performed so that the thickness of the spacer 320 is in the range of 10 Å to 50 Å.

The spacer 320 may include gallium-zinc oxide (GaZnO) formed by supplying a gas containing gallium (Ga) into the chamber, supplying a gas containing zinc (Zn) into the chamber, and supplying a gas containing oxygen into the chamber.

The spacer 320 may be formed by sequentially supplying a gas containing a gallium (Ga) precursor and oxygen, and a gas containing zinc precursor and oxygen, and there is no particular order in supplying these gases. The process of forming the spacer 320 may be performed by an ALD process of repeatedly supplying the gas containing a gallium (Ga) precursor and oxygen to form a GaO layer and supplying the gas containing zinc (Zn) precursor and oxygen to form an ZnO layer. At this time, the process of forming the GaO layer and the ZnO layer may be repeatedly performed so that the thickness of the spacer 320 is in the range of 10 Å to 50 Å.

The spacer 320 may include indium-gallium-zinc oxide (InGaZnO) formed by supplying a gas containing gallium (Ga) into the chamber, supplying a gas containing indium (In) and zinc (Zn) into the chamber, and supplying a gas containing oxygen into the chamber.

The spacer 320 may be formed by sequentially supplying a gas containing a gallium (Ga) precursor and oxygen, a gas containing indium precursor and oxygen, and a gas containing a zinc precursor and oxygen, and there is no particular order in supplying these gases.

The process of forming the spacer 320 may be performed by an ALD process of repeatedly supplying the gas containing a gallium (Ga) precursor and oxygen to form a GaO layer, supplying the gas containing indium (In) precursor and oxygen to form an InO layer and supplying the gas containing zinc (Zn) precursor and oxygen to form an ZnO layer. At this time, the process of forming the GaO layer, the InO layer and the ZnO layer may be repeatedly performed so that the thickness of the spacer 320 is in the range of 10 Å to 50 Å.

In the process of forming the spacer 320, a dopant may be additionally included.

The second channel layer 330 may include indium-zinc oxide (InZnO) formed by supplying a gas containing indium (In) and zinc (Zn) into the chamber and supplying a gas containing oxygen into the chamber.

The second channel layer 330 may be formed by sequentially supplying a gas containing indium (In) precursor and oxygen, and a gas containing zinc (Zn) precursor and oxygen, and there is no particular order in supplying these gases.

The process of forming the second channel layer 330 may be performed by an ALD process of repeatedly supplying the gas containing indium (In) precursor and oxygen to form an InO layer and supplying the gas containing zinc (Zn) precursor and oxygen to form an ZnO layer. At this time, the process of forming the InO layer and the ZnO layer may be repeatedly performed so that the thickness of the second channel layer 330 is in the range of 50 Å to 100 Å.

The thicknesses of each of the first channel layer 310 and the second channel layer 330 may be in the range of 50 Å to 100 Å. The thickness of the spacer 320 may be thinner than the thickness of the first channel layer 310 and the second channel layer 330, and may be specifically in the range of 10 Å to 50 Å.

The content of indium in the first channel layer 310 may be higher than the content of indium in the second channel layer 330. Alternatively, the content of indium in the second channel layer 330 may be higher than the content of indium in the first channel layer 310.

Next, as shown in FIG. 2C, the first channel layer 310, the spacer 320, and the second channel layer 330 are patterned. Accordingly, the first channel layer 310, the spacer 320, and the second channel layer 330 may be patterned to have the same structure. That is, one end of the first channel layer 310, spacer 320, and second channel layer 330 may match each other, and the other end of the first channel layer 310, spacer 320, and second channel layer 330 may match each other.

In some cases, by using the shadow mask in the above-described process of FIG. 2B, the process of FIG. 2C may be omitted. In other words, when the first channel layer 310, spacer 320, and second channel layer 330 are formed in-situ in one deposition chamber, a shadow mask may be used to form the first channel layer 310, spacer 320, and second channel layer 330 which have patterns of the aforementioned FIG. 2C.

Next, as shown in FIG. 2D, a gate insulating layer 400 and a gate electrode 500 are formed on the active layer 300.

After the gate insulating layer 400 and the gate electrode 500 are formed on the entire upper surface of the active layer 300, the gate insulating layer 400 and the gate electrode 500 may be patterned. Accordingly, the gate electrode 500 and the gate insulating layer 400 are formed so that a part of the upper surface of the active layer 300 may be exposed.

Next, as shown in FIG. 2E, an interlayer insulating layer 600 is formed on the gate electrode 500, and a first contact hole CHI and a second contact hole CH2 are formed in the interlayer insulating layer 600.

One side of the upper surface of the active layer 300 is exposed by the first contact hole CH1, and the other side of the upper surface of the active layer 300 is exposed by the second contact hole CH2.

Next, as shown in FIG. 2F, a source electrode 710 and a drain electrode 720 are formed on the interlayer insulating layer 600.

The source electrode 710 is in contact with one side of the active layer 300, more specifically, the upper surface of one side of the second channel layer 330 through the first contact hole CH1. The drain electrode 720 is in contact with the other side of the active layer 300, more specifically the upper surface of the other side of the second channel layer 330 through the second contact hole CH2.

Hereinabove, the embodiments of the present inventive concept have been described in more detail with reference to the accompanying drawings, but the present inventive concept is not limited to the embodiments and may be variously modified within a range which does not depart from the technical spirit of the present inventive concept. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. A method of manufacturing an oxide transistor, the method comprising:
a step of forming a first channel layer by supplying a gas containing indium (In) and zinc (Zn) and supplying a gas containing oxygen;
a step of forming a spacer on the first channel layer by supplying a gas containing gallium (Ga) and supplying a gas containing oxygen; and
a step of forming a second channel layer on the spacer by supplying a gas containing indium (In) and zinc (Zn) and supplying a gas containing oxygen.

2. The method of manufacturing an oxide transistor of claim 1, wherein the first channel layer, the spacer, and the second channel layer is formed in-situ in one chamber.

3. The method of manufacturing an oxide transistor of claim 1, wherein a content of indium in the first channel layer is higher than a content of indium in the second channel layer.

4. The method of manufacturing an oxide transistor of claim 1, wherein a content of indium in the second channel layer is higher than a content of indium in the first channel layer.

5. The method of manufacturing an oxide transistor of claim 1, wherein the spacer further comprises at least one of indium (In) and Zinc (Zn).

6. The method of manufacturing an oxide transistor of claim 1, wherein a thickness of at least one of the first channel layer and the second channel layer is in the range of 50 Å to 100 Å.

7. The method of manufacturing an oxide transistor of claim 1, wherein a thickness of the spacer is thinner than each of a thickness of the first channel layer and a thickness of the second channel layer.

8. The method of manufacturing an oxide transistor of claim 7, wherein a thickness of the spacer is in the range of 10 Å to 50 Å.

9. An oxide transistor comprising:
a first channel layer including indium-zinc oxide (InZnO);
a second channel layer including indium-zinc oxide (InZnO) and being on the first channel layer; and
a spacer including gallium oxide (GaO) and being between the first channel layer and the second channel layer.

10. The oxide transistor of claim 9, wherein the spacer further comprises at least one of indium (In) and Zinc (Zn).

11. The oxide transistor of claim 9, wherein a thickness of at least one of the first channel layer and the second channel layer is in the range of 50 Å to 100 Å.

12. The oxide transistor of claim 9, wherein a thickness of the spacer is thinner than each of a thickness of the first channel layer and a thickness of the second channel layer.

13. The oxide transistor of claim 9, wherein a thickness of the spacer is in the range of 10 Å to 50 Å.

14. The oxide transistor of claim 9, wherein the first channel layer, the spacer, and the second channel layer is formed in-situ in one chamber.

15. The oxide transistor of claim 9, wherein a content of indium in the first channel layer is higher than a content of indium in the second channel layer.

16. The oxide transistor of claim 9, wherein a content of indium in the second channel layer is higher than a content of indium in the first channel layer.

17. A method of manufacturing an oxide transistor, the method comprising:
a step of forming a first channel layer by sequentially supplying a gas containing indium (In) precursor and oxygen, and a gas containing zinc (Zn) precursor and oxygen;
a step of forming a spacer on the first channel layer by supplying a gas containing gallium (Ga) precursor and oxygen; and
a step of forming a second channel layer on the spacer by sequentially supplying a gas containing indium (In) precursor and oxygen, and a gas containing zinc (Zn) precursor and oxygen.

18. The method of manufacturing an oxide transistor of claim 17, wherein at least one of the step of forming the first channel layer and the step of forming the second channel layer is performed by an ALD process of repeatedly supplying the gas containing indium (In) precursor and oxygen to form an InO layer and supplying the gas containing zinc (Zn) precursor and oxygen to form an ZnO layer, and
wherein the step of forming the spacer is performed by an ALD process of repeatedly supplying the gas containing gallium (Ga) precursor and oxygen to form a GaO layer.

19. The method of manufacturing an oxide transistor of claim 18, wherein the process of forming the InO layer and the ZnO layer is repeatedly performed so that a thickness of the first channel layer or the second channel layer is in the range of 50 Å to 100 Å, and wherein the process of forming the GaO layer is repeatedly performed so that a thickness of the spacer is in the range of 10 Å to 50 Å.
